(19) United States
(12) Patent Application Publication
(10) Pub. No.: US 2008/0136037 A1
(43) Pub. Date: Jun. 12, 2008

(54) METHOD FOR MANUFACTURING SEMICONDUCTOR DEVICE AND SEMICONDUCTOR DEVICE

(75) Inventor: Shinichi Arakawa, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 11/695,945

(22) Filed: Apr. 3, 2007

(30) Foreign Application Priority Data
Apr. 5, 2006 (JP) 2006-103809

(51) Int. Cl. H01L 21/768; H01L 23/48

(52) U.S. Cl. 257/773; 438/637; 257/E21.585; 257/E23.01

(57) ABSTRACT

A method for manufacturing a semiconductor device, the method including: the first step of forming an insulating film over a substrate of which surface side has a first conductive layer, and forming a recess in the insulating film by dry etching; the second step of carrying out plasma treatment for the insulating film with use of a gas that contains carbon or silicon; and the third step of forming a second conductive layer buried in the recess for which the plasma treatment has been carried out.

### CROSS REFERENCES TO RELATED APPLICATIONS

The present invention contains subject matter related to Japanese Patent Application JP 2006-103809 filed with the Japanese Patent Office on Apr. 5, 2006, the entire contents of which being incorporated herein by reference.

### BACKGROUND OF THE INVENTION

1. Field of the Invention

The present invention relates to a method for manufacturing a semiconductor device and a semiconductor device, and particularly to a method for manufacturing a semiconductor device and a semiconductor device that are suitable to form a multilevel interconnect structure with use of a low dielectric constant film as an interlayer insulating film.

2. Description of the Related Art

Recent trend of semiconductor devices toward higher integration and smaller line width creates the need for reduction in RC delay in particular. To meet this need, it has been attempted to change an interconnect material from aluminum (Al) to copper (Cu), which has lower resistivity, and employ as an insulating film material a low dielectric constant (low-k) film having a dielectric constant lower than that of a silicon oxide (SiO₂), which is employed in existing devices. As the low-k films, insulating films having a dielectric constant k lower than 3.0 are being studied. Among such low-k films are e.g. a hydrogen silsesquioxane (HSQ) film, methyl silsesquioxane (MSQ) film, and aromatic-containing organic insulating film.

In recent years, a hybrid structure formed of a combination of an aromatic-containing organic insulating film and an inorganic insulating film composed of polymethylsiloxane or MSQ has been widely employed because it allows a dual damascene process to be carried out easily. For the 45-nm and 32-nm generations, a film having a dielectric constant lower than 2.5 is expected as an interlayer insulating film.

With reference to FIGS. 3A to 3H, a description will be made below about one example of a method for manufacturing a multilayer interconnect structure through a dual damascene method in which a porous MSQ film is used as an interlayer insulating film. Referring initially to FIG. 3A, in an interconnect trench 13 provided in an interlayer insulating film 12 composed of SiO₂ on a semiconductor substrate 11 formed of a silicon substrate, a lower interconnect 15 composed of Cu is provided, with intermediary of a tantalum (Ta) barrier film 14. Furthermore, an etching stopper film 16 composed of silicon carbonitride (SiCN) is formed to cover the lower interconnect 15 and the interlayer insulating film 12, and then a low-k film formed of a porous MSQ film with a dielectric constant lower than 2.5 is formed as an interlayer insulating film 17 over the etching stopper film 16.

Subsequently, as shown in FIG. 3B, a resist pattern R having a contact hole pattern is formed on the interlayer insulating film 17 by general lithography. Referring next to FIG. 3C, a contact hole 18 that reaches the etching stopper film 16 is formed in the interlayer insulating film 17 through plasma etching with use of the resist pattern R (see FIG. 3B) as the mask. After the etching, the resist pattern R is removed.

Subsequently, as shown in FIG. 3D, a resist pattern R′ having an interconnect trench pattern is formed on the interlayer insulating film 17 by general lithography in such a way that the contact hole 18 is filled with the resist pattern R′. Referring next to FIG. 3E, an interconnect trench 19 in communication with the contact hole 18 is formed in the interlayer insulating film 17 through etching with use of the resist pattern R′ (see FIG. 3D) as the mask. After the etching, the resist pattern R′ is removed.

Subsequently, as shown in FIG. 3F), the etching stopper film 16 exposed at the bottom of the contact hole 18 is removed to thereby expose the surface of the lower interconnect 15. The exposed surface of the lower interconnect 15 is cleaned with an organic cleaning liquid.

Referring next to FIG. 3G, a barrier film 20 composed of Ta is formed on the interlayer insulating film 17 in such a manner as to cover the inner walls of the interconnect trench 19 and the contact hole 18. Subsequently, as shown in FIG. 3H, a conductive film (not shown) composed of Cu is formed on the barrier film 20 in such a manner as to cover the contact hole 18 and the interconnect trench 19, on which the barrier film 20 has been formed. Thereafter, heat treatment is carried out to thereby grow Cu crystals in the conductive film. Subsequently, the conductive film and the barrier film 20 are removed by chemical mechanical polishing (CMP) until the surface of the interlayer insulating film 17 is exposed, so that a via 21 is formed in the contact hole 18 and an upper interconnect 22 is formed in the interconnect trench 19.

If the interlayer insulating film 17 is formed of a low-k film with a dielectric constant lower than 2.5, such as a porous MSQ film, as described above, the film density of the interlayer insulating film 17 is low, which makes the interlayer insulating film 17 susceptible to plasma damage at the time of the etching process.

As a countermeasure against the damage to the low-k film due to etching, a damage recovery technique has been researched and reported. In this technique, after an etching process for an interlayer insulating film, annealing treatment is carried out with use of tetra-methylcyclotetrasiloxane (TMCTS) for the treatment atmosphere, to thereby repair side walls exposed due to the etching process (refer to e.g. Y. Oku, et al., Novel Self-Assembled Ultra-Low-k Porous Silica Films with High Mechanical Strength for 45 nm BEOL Technology, “International ELECTRON DEVICE Meeting” (USA) IEEE, 2003).

### SUMMARY OF THE INVENTION

However, to achieve sufficient repair effect through the above-described method, high-temperature treatment at about 400° C. is necessary. If the interlayer insulating film includes an organic material film of which heat resistance is poor in particular, this high temperature is an unacceptable condition in terms of device reliability. For example, this high-temperature treatment would possibly cause deterioration of the initial characteristics due to removal or adhesion lowering of a barrier film attributed to promotion of degassing from the interlayer insulating film, and void formation attributed to suction-up of a via part in a dual damascene structure.

Furthermore, failure in achieving sufficient repair effect results in moisture absorption in the interlayer insulating film. If a porous film provided with pores for reduction in the dielectric constant is used in particular, the existence of the pores accelerates the moisture absorption. Furthermore, at the time of cleaning treatment subsequent to the etching process, the pores form the entry paths for the cleaning chemical.

Therefore, there is a problem that as shown in FIG. 4, the barrier film 20 is easily oxidized due to degassing from the interlayer insulating film 17. Furthermore, if the aspect ratio of the contact hole 18 is high in particular, it is difficult for a deposition gas to reach the inner wall of the contact hole 18. Hence, the thickness of the formed barrier film 20 is small, which significantly easily oxidizes the barrier film 20. The oxidation of the barrier film 20 deteriorates the barrier property, and therefore causes a leakage M of the conductive material (metal) from the via 21 into the interlayer insulating film 17. Furthermore, because the adhesion between the interlayer insulating film 17 and the barrier film 20 is also deteriorated, a void V is easily generated in the via 21, which induces reliability failure such as stress migration (SM) and electro migration (EM). Moreover, the oxidation of the barrier film 20 leads to oxidation of the via 21, and therefore the resistance is increased.

There is a need for the present invention to provide a method for manufacturing a semiconductor device in which damage due to dry etching is repaired without high-temperature treatment at 400° C. or higher to prevent degassing from an interlayer insulating film, and to provide a semiconductor device obtained by this method.

According to an embodiment of the present invention, there is provided a method for manufacturing a semiconductor device. The method includes: the first step of forming an insulating film over a substrate of which surface side has a first conductive layer, and forming a recess in the insulating film by dry etching; the second step of carrying out plasma treatment for the insulating film with use of a gas that contains carbon or silicon; and the third step of forming a second conductive layer buried in the recess for which the plasma treatment has been carried out.

According to this method for manufacturing a semiconductor device, the plasma treatment with the gas containing carbon or silicon is carried out for the insulating film in which the recess has been formed through dry etching. Thus, OH groups that have adhered to the inner wall of the recess and cause degassing are desorbed, and the surface side of the insulating film exposed at the inner wall of the recess is densified, so that a dense layer is formed. Thus, damage to the insulating film exposed at the inner wall of the recess due to the dry etching is repaired without heat treatment at 400° C. or higher, and hence degassing from the insulating film is suppressed. If plasma treatment with a gas containing carbon is carried out in particular, dangling bonds exposed at the sidewall of the recess are terminated by carbon-containing groups, and a seal layer containing carbon is formed on the surface of the dense layer. This significantly suppresses degassing from the insulating film. Therefore, when a barrier film for preventing diffusion of a conductive material from the second conductive layer into the insulating film is formed in such a manner as to cover the inner wall of the recess, oxidation of the barrier film is suppressed. This suppresses deterioration of the barrier property due to oxidation of the barrier film, which prevents leakage of the conductive material into the insulating film and hence can prevent short-circuit of the second conductive layer. In addition, lowering of the adhesion between the barrier film and the insulating film attributed to oxidation of the barrier film is suppressed, and therefore generation of a void in the second conductive layer is prevented, which avoids failure in the reliability against SM and EM. Moreover, oxidation of the second conductive layer due to oxidation of the barrier film is prevented, and thus an increase in the resistance of the second conductive layer is avoided.

According to another embodiment of the present invention, there is provided a semiconductor device including: a substrate configured to have a first conductive layer on the surface side; an insulating film configured to be provided over the substrate; and a second conductive layer configured to be buried in a recess that is provided in the insulating film and reaches the first conductive layer. In this device, a dense layer arising from densification of the insulating film is provided in a part of the insulating film near the interface between the insulating film and the second conductive layer, and a seal layer containing carbon is provided between the dense layer and the second conductive layer.

According to this semiconductor device, the dense layer is provided in a part of the insulating film near the interface with the second conductive layer, and the seal layer containing carbon is provided between the dense layer and the second conductive layer. These features significantly suppress degassing from the insulating film. Thus, when a barrier film for preventing diffusion of a conductive material from the second conductive layer into the insulating film is provided in such a manner as to cover the inner wall of the recess, oxidation of the barrier film is suppressed. This suppresses deterioration of the barrier property due to oxidation of the barrier film, which prevents leakage of the conductive material into the insulating film and hence can prevent short-circuit of the second conductive layer. In addition, lowering of the adhesion between the barrier film and the insulating film attributed to oxidation of the barrier film is suppressed, and therefore generation of a void in the second conductive layer is prevented, which avoids failure in the reliability against SM and EM. Moreover, oxidation of the second conductive layer due to oxidation of the barrier film is prevented, and thus an increase in the resistance of the second conductive layer is avoided.

According to another embodiment of the present invention, there is provided another semiconductor device including: a substrate configured to have a first conductive layer on the surface side; an insulating film configured to be provided over the substrate; and a second conductive layer configured to be buried in a recess that is provided in the insulating film and reaches the first conductive layer. In this device, a dense layer arising from densification of the insulating film is provided in a part of the insulating film near the interface between the insulating film and the second conductive layer, and a silicide layer is provided in a part of the first conductive layer near the interface between the first conductive layer and the second conductive layer.

According to this semiconductor device, the dense layer is provided in a part of the insulating film near the interface with the second insulating layer, which suppresses degassing from the insulating film. Thus, when a barrier film for preventing diffusion of a conductive material from the second conductive layer into the insulating film is provided in such a manner as to cover the inner wall of the recess, oxidation of the barrier film is suppressed. This suppresses deterioration of the barrier property due to oxidation of the barrier film, which prevents leakage of the conductive material into the insulating film and hence can prevent short-circuit of the second conductive layer. In addition, lowering of the adhesion between the barrier film and the insulating film attributed to oxidation of the barrier film is suppressed, and therefore generation of a void in the second conductive layer is prevented, which avoids failure in the reliability against SM and EM. Moreover, oxidation of the second conductive layer due to oxidation of the barrier film is prevented, and thus an increase in the resistance of the second conductive layer is avoided. Moreover, because the silicide layer is formed in a part of the first conductive layer near the interface with the second conductive layer, the SM resistance and the EM resistance can be enhanced.

As described above, in a method for manufacturing a semiconductor device and a semiconductor device obtained by this method according to embodiments of the present invention, short-circuit of the second conductive layer can be prevented, and the SM resistance and the EM resistance can be enhanced. Furthermore, an increase in the resistance of the second conductive layer can be prevented. Consequently, the reliability of the interconnect structure can be enhanced, which can realize high-performance CMOS devices. Therefore, the performance of computers, game apparatuses, mobile products, and so on can be significantly enhanced.

### BRIEF DESCRIPTION OF THE DRAWINGS

FIGS. 1A to 1I are sectional views for explaining manufacturing steps of a method for manufacturing a semiconductor device according to a first embodiment of the present invention;

FIGS. 2A to 2I are sectional views for explaining manufacturing steps of a method for manufacturing a semiconductor device according to a second embodiment of the invention;

FIGS. 3A to 3H are sectional views for explaining manufacturing steps of an existing method for manufacturing a semiconductor device; and

FIG. 4 is a sectional view for explaining problems in the existing method for manufacturing a semiconductor device.

### DETAILED DESCRIPTION OF THE PREFERRED EMBODIMENTS

Embodiments of the present invention will be described in detail below with reference to the accompanying drawings.

### First Embodiment

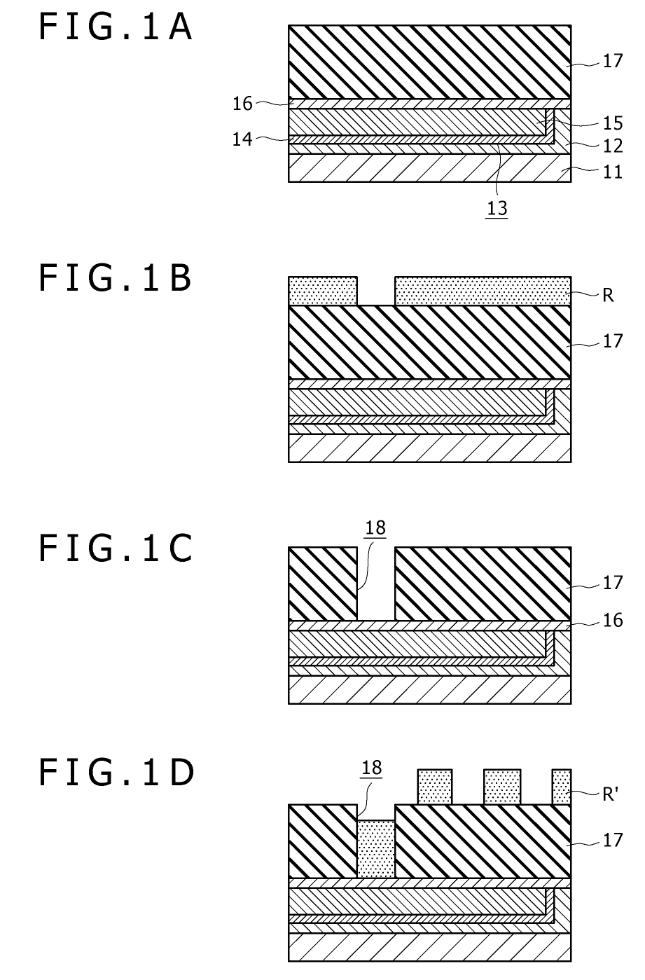

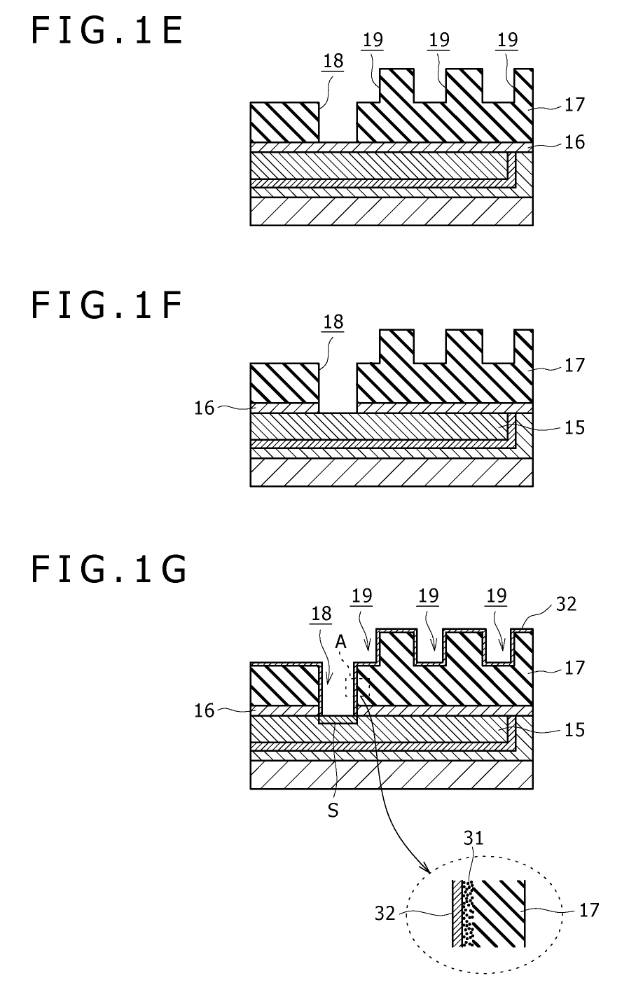

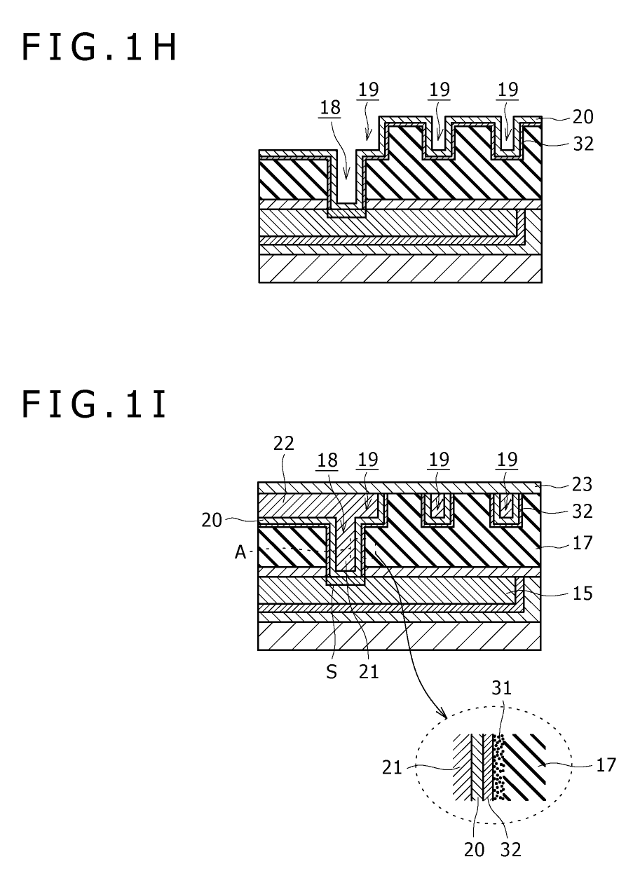

One example of a method for manufacturing a semiconductor device according to an embodiment of the present invention will be described below with reference to FIGS. 1A to 1I as sectional views of manufacturing steps. The present embodiment relates to a method for forming a multilevel interconnect structure formed of Cu and low-k films by use of a dual damascene method. The same components in the present embodiment as those in the method for manufacturing a semiconductor device described above as the related art are given the same symbols.

Referring initially to FIG. 1A, an interlayer insulating film 12 composed of e.g. SiO₂ is provided on a semiconductor substrate 11 over which semiconductor elements such as transistors have been formed. In an interconnect trench 13 provided in the interlayer insulating film 12, a lower interconnect 15 (first conductive layer) that is composed of e.g. Cu and has a thickness of 60 nm is formed with intermediary of a barrier film 14 composed of e.g. Ta. These components 11 to 15 correspond to the substrate set forth in the claims.

On the lower interconnect 15 and the interlayer insulating film 12, an etching stopper film 16 composed of e.g. SiCN is formed to a film thickness of 30 nm by plasma enhanced chemical vapor deposition (PE-CVD).

An interlayer insulating film 17 is formed on the etching stopper film 16. Specifically, the interlayer insulating film 17 that is formed of a MSQ porous film and has a film thickness of 250 nm is formed by e.g. coating or CVD. The dielectric constant of the MSQ porous film is at most 2.5. It is preferable that the interlayer insulating film 17 be formed of a low-k film having a dielectric constant lower than that of a silicon oxide. Examples of such an interlayer insulating film 17 include inorganic insulating films such as a polymethylsilane film, HSQ film and MSQ film and aromatic-containing organic insulating films such as a polyarylether (PAE) film. In particular, the interlayer insulating film 17 including a porous film of any of these low-k films is preferable. This is because the film density of such an interlayer insulating film 17 is lower compared with a non-porous film, and therefore the dielectric constant thereof is also lower, which achieves reduced interconnect capacitance.

Referring next to FIG. 1B, e.g. a chemically amplified ArF resist is applied on the interlayer insulating film 17, and then a pattern of a contact hole with a diameter of 60 nm is formed in this resist by general lithography to thereby form a resist pattern R.

Subsequently, as shown in FIG. 1C, a contact hole 18 that reaches the etching stopper film 16 is formed in the interlayer insulating film 17 through plasma etching in which the resist pattern R (see FIG. 1B) is used as the mask and a fluorocarbon (CF) gas is employed. Because the interlayer insulating film 17 is formed of an MSQ porous film, it has a film structure containing a large number of methyl groups. Therefore, the plasma generated at the time of the formation of the contact hole 18 damages the methyl groups exposed at the sidewall of the contact hole 18. Accordingly, dangling bonds are exposed at the damaged part, and hence moisture is easily absorbed through the damaged part. After the formation of the contact hole 18, the remaining resist pattern R is removed by ashing with an O₂ gas. It is preferable that this ashing be carried out under a low pressure less than 6.7 Pa for minimization of damage to the interlayer insulating film 17. In this example, the ashing is carried out under e.g. 2.7 Pa.

Subsequently, as shown in FIG. 1D, a chemically amplified ArF resist is applied on the interlayer insulating film 17 again in such a way that the contact hole 18 is filled with the resist, and then a resist pattern R′ having an interconnect trench pattern is formed by general lithography.

Referring next to FIG. 1E, an interconnect trench 19 that communicates with the contact hole 18 and has a depth of 140 nm is formed in the interlayer insulating film 17 through dry etching in which the resist pattern R′ (see FIG. 1D) is used as the mask and a CF gas is employed. Also in this dry etching, the plasma damages methyl groups exposed at the sidewall of the interconnect trench 19. Accordingly, dangling bonds are exposed at the damaged part of the interlayer insulating film 17, and hence moisture is easily absorbed through the damaged part. After the formation of the interconnect trench 19, the resist pattern R′ is removed by ashing with an O₂ gas under a low pressure.

Subsequently, as shown in FIG. 1F, the etching stopper film 16 exposed at the bottom of the contact hole 18 is removed through dry etching with a CF gas to thereby expose the lower interconnect 15. The interconnect trench 19 and the contact hole 18 in communication with the bottom of the interconnect trench 19 correspond to the recess set forth in the claims. The exposed surface of the lower interconnect 15 is cleaned with an organic cleaning liquid. Due to this cleaning, the insulating film exposed at the sidewalls of the interconnect trench 19 and the contact hole 18 absorb moisture, and therefore OH groups as a factor in degassing adhere to the dangling bonds exposed at the sidewalls.

Referring next to FIG. 1G, plasma treatment with a gas containing both carbon (C) and silicon (Si) is carried out for the interlayer insulating film 17. In this example, dimethylphenylsilane (DMPS) is used as the gas. This plasma treatment desorbs the OH groups that have adhered to the sidewalls of the interconnect trench 19 and the contact hole 18 and cause degassing, and forms a dense layer 31 arising from densification of the interlayer insulating film 17 on the surface side of the interlayer insulating film 17 as shown in the enlarged drawing of the area A. Furthermore, because the gas contains C, the dangling bonds exposed at the sidewalls of the interconnect trench 19 and the contact hole 18 are terminated by carbon-containing groups, and a seal layer 32 formed of an SiₓC_{y} film containing carbon is formed on the interlayer insulating film 17 in such a manner as to cover the inner walls of the interconnect trench 19 and the contact hole 18, over which the dense layer 31 has been provided. This repairs the damage to the interlayer insulating film 17 exposed at the sidewalls of the interconnect trench 19 and the contact hole 18 due to the dry etching. Consequently, moisture absorption in the interlayer insulating film 17 is suppressed, and degassing of water remaining in the interlayer insulating film 17 is prevented. Furthermore, the seal layer 32 that covers the lower interconnect 15 at the bottom of the contact hole 18 is diffused into the surface side of the lower interconnect 15 due to heat in this plasma treatment, so that a silicide layer S is formed. This enhances the SM resistance and the EM resistance.

It is preferable that the seal layer 32 be formed as an extremely thin film of which thickness is smaller than 0.5 nm through control of conditions of the plasma treatment. If the seal layer 32 is an extremely thin film, the dielectric constant of the interlayer insulating film 17 does not increase, and an increase in the resistance of the via due to the provision of the silicide layer S on the surface side of the lower interconnect 15 can be suppressed within an allowable range.

One example of the plasma treatment conditions is as follows: the carrier gas contains DMPS precursor species and helium (He) and is supplied at a gas flow rate of DMPS/He=500/1000 ml/min; the substrate RF bias power is 150 W; the pressure is 670 Pa; the temperature is 350° C.; and the treatment time is 15 sec.

In this example, DMPS is used as a gas containing both C and Si. However, the present invention is not limited thereto. Any of e.g. tetramethylcyclotetrasiloxane (TMCTS), octamethylcyclotetrasiloxane (OMCTS), trimethylsilane (3MS), and tetramethylsilane (4MS) may be used. In particular, it is preferable to supply a compound having in its molecule a benzene ring or another cyclic structure, such as DMPS. This is because the cyclic structure serves as a steric constraint and hence a low deposition rate can be obtained easily, which allows the seal layer 32 having a thickness smaller than 0.5 nm to be deposited with good reproducibility.

In this example, a gas containing both C and Si is employed in the plasma treatment. However, the present invention is not limited thereto as long as the treatment gas contains C or Si. As elements other than C or Si, any of e.g. hydrogen (H), oxygen (O), and nitrogen (N) may also be contained. Among C-containing gases that do not contain Si are e.g. a methane (CH₄) gas and ethylene (C₂H₄) gas. Among Si-containing gases that do not contain C is e.g. a silane (SiH₄) gas.

If plasma treatment is carried out by using the above-described C-containing gas, OH groups that have adhered to the sidewalls of the interconnect trench 19 and the contact hole 18 are desorbed, and the dense layer 31 is formed on the surface side of the interlayer insulating film 17. Furthermore, dangling bonds exposed at the sidewalls of the interconnect trench 19 and the contact hole 18 are terminated by carbon-containing groups, and the seal layer 32 containing C is formed on the interlayer insulating film 17 in such a manner as to cover the sidewalls of the interconnect trench 19 and the contact hole 18, over which the dense layer 31 has been provided. In the present case, the seal layer 32 on the lower interconnect 15 exposed at the bottom of the contact hole 18 is not turned into a silicide but remains as it is. However, because the seal layer 32 is an extremely thin film of which thickness is smaller than 0.5 nm, the resistance of the via to be described later is suppressed within an allowable range and hence the interconnect reliability is maintained even if the seal layer 32 is not removed.

If plasma treatment is carried out by using the above-described Si-containing gas, OH groups that have adhered to the sidewalls of the interconnect trench 19 and the contact hole 18 are desorbed, and the dense layer 31 is formed on the surface side of the interlayer insulating film 17. In this case, due to heat in the plasma treatment, the seal layer 32 on the lower interconnect 15 exposed at the bottom of the contact hole 18 is diffused into the surface side of the lower interconnect 15 to become the silicide layer S. This enhances the SM resistance and the EM resistance.

After the seal layer 32 has been formed in the above-described manner, as shown in FIG. 1H, a barrier film 20 that is composed of e.g. Ta and has a film thickness of 7 nm is formed on the seal layer 32 by e.g. sputtering or CVD in such a manner as to cover the inner walls of the interconnect trench 19 and the contact hole 18.

Referring next to FIG. 1I, a seed layer (not shown) that is composed of e.g. Cu and has a film thickness of 45 nm is formed on the barrier film 20 by e.g. sputtering or CVD. Subsequently, a conductive film (not shown) composed of e.g. Cu is deposited on the barrier film 20 by electroplating (ECP) or CVD in such a manner as to fill the interconnect trench 19 and the contact hole 18. Thereafter, annealing treatment to grow Cu crystals is carried out at 250° C. for 90 seconds.

Subsequently, the conductive film, the barrier film 20 and the seal layer 32 are removed by e.g. CMP until the surface of the interlayer insulating film 17 is exposed, so that a via 21 (second conductive layer) is formed in the contact hole 18 and an upper interconnect 22 (second conductive layer) is formed in the interconnect trench 19. This results in the state in which the silicide layer S is provided in a part of the lower interconnect 15 near the interface with the via 21. Thereafter, an etching stopper film 23 composed of e.g. SiCN is formed on the upper interconnect 22 and the interlayer insulating film 17.

Although the seal layer 32 is removed by CMP in the present embodiment, the seal layer 32 may not be removed. In this example, the lower interconnect 15, the via 21 and the upper interconnect 22 are composed of Cu. However, the present invention is not limited thereto. Instead of Cu, any of silver (Ag), gold (Au), aluminum (Al) and an alloy of these metals may be used.

As the subsequent steps, the steps from the step of forming the interlayer insulating film 17 described with FIG. 1A to the step of forming the etching stopper film 23 described with FIG. 1I are repeatedly carried out, to thereby manufacture a multilevel interconnect structure.

According to the above-described method for manufacturing a semiconductor device and a semiconductor device, plasma treatment is carried out by using a gas containing DMPS for the interlayer insulating film 17 in which the interconnect trench 19 and the contact hole 18 have been formed through dry etching. Thus, OH groups that have adhered to the sidewalls of the interconnect trench 19 and the contact hole 18 are desorbed, and the surface side of the interlayer insulating film 17 is densified, so that the dense layer 31 is formed as shown in the enlarged drawing of the area A. Furthermore, dangling bonds exposed at the sidewalls of the interconnect trench 19 and the contact hole 18 are terminated by carbon-containing groups, and the seal layer 32 formed of an SiₓC_{y} film is formed on the surface of the dense layer 31. Thus, the damage to the interlayer insulating film 17 due to the dry etching is repaired without heat treatment at 400° C. or higher, and hence degassing from the interlayer insulating film 17 is suppressed. Consequently, oxidation of the barrier film 20 is suppressed.

This suppresses deterioration of the barrier property due to oxidation of the barrier film 20, which prevents leakage of the conductive material into the interlayer insulating film 17 and hence can prevent short-circuit of the via 21. In addition, lowering of the adhesion between the barrier film 20 and the interlayer insulating film 17 is suppressed, and therefore generation of a void in the via 21 is prevented, which avoids deterioration of the SM resistance and the EM resistance. Moreover, oxidation of the via 21 due to oxidation of the barrier film 20 is prevented, and thus an increase in the resistance of the via 21 is avoided. Consequently, the reliability of the interconnect structure can be enhanced, which can realize high-performance CMOS devices. Therefore, the performance of computers, game apparatuses, mobile products, and so on can be significantly enhanced.

Moreover, according to the present embodiment, the silicide layer S is formed in a part of the lower interconnect 15 near the interface with the via 21, which can enhance the SM resistance and the EM resistance.

In the above-described example, as described with FIG. 1G, plasma treatment with DMPS is carried out after the step of removing the etching stopper film 16 at the bottom of the contact hole 18 to thereby expose the lower interconnect 15 and before the step of forming the barrier film 20. However, in an embodiment of the present invention, the plasma treatment may be carried out at any timing as long as the timing is subsequent to the step of forming the interconnect trench 19 or the contact hole 18 and previous to the step of forming the barrier film 20.

For example, the plasma treatment may be carried out after the step described with FIG. 1C, in which the contact hole 18 that reaches the etching stopper film 16 is formed in the interlayer insulating film 17, and before the step described with FIG. 1D, in which the resist pattern R′ is formed. Alternatively, the plasma treatment may be carried out after the step described with FIG. 1E, in which the interconnect trench 19 is formed in the interlayer insulating film 17, and before the step described with FIG. 1F, in which the etching stopper film 16 at the bottom of the contact hole 18 is removed. More alternatively, plural times of the plasma treatment may be carried out in such a way that the treatment is carried out at the above-described two timings and more other timings. However, it is difficult to form the barrier film 20 on the sidewall of the contact hole 18, which has a high aspect ratio, and hence the barrier film 20 that covers the sidewall of the contact hole 18 is easily oxidized. Therefore, it is preferable to carry out the plasma treatment after the contact hole 18 has been provided in the interlayer insulating film 17. Furthermore, it is preferable to carry out the plasma treatment after the lower interconnect 15 has been exposed at the bottom of the contact hole 18 because the silicide layer S is formed on the surface side of the lower interconnect 15.

### Second Embodiment

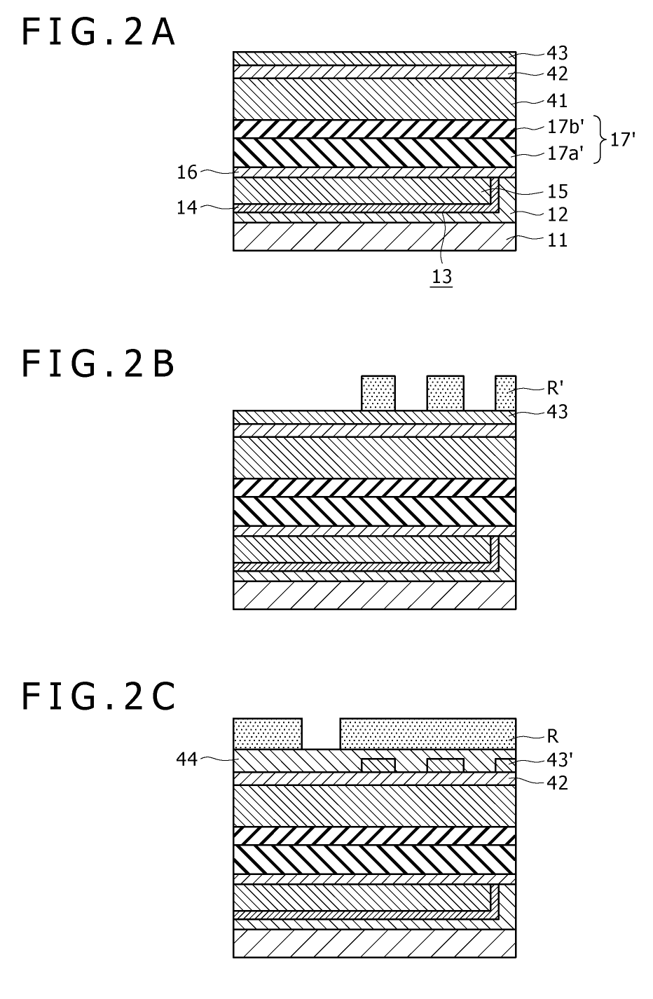

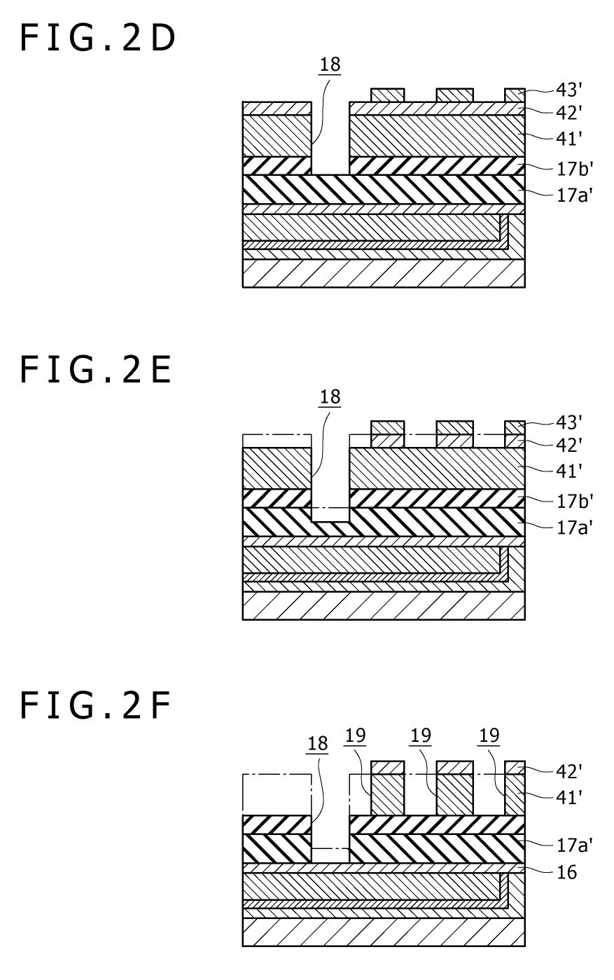

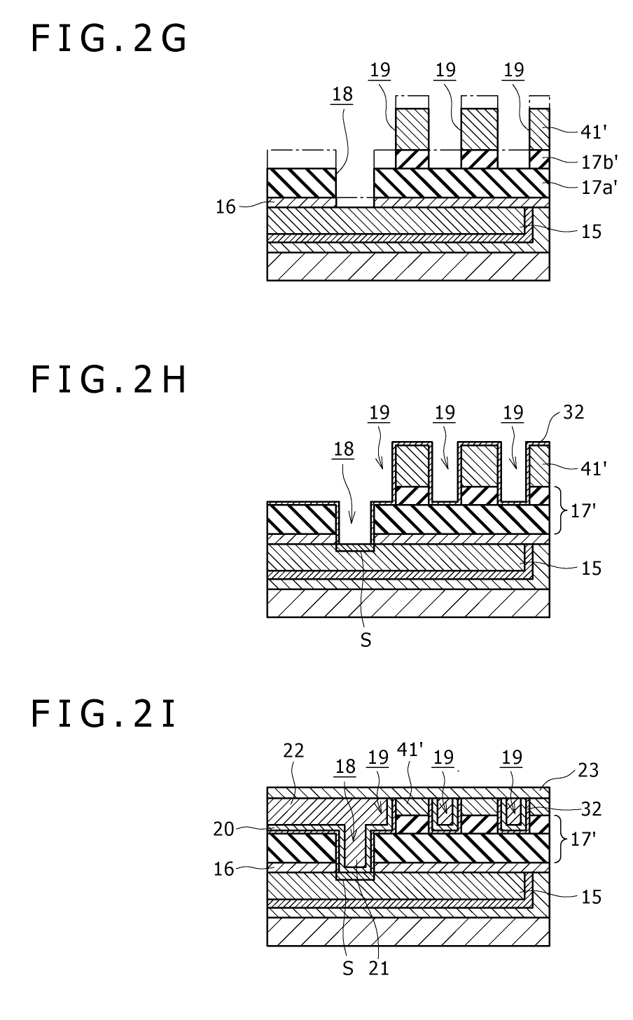

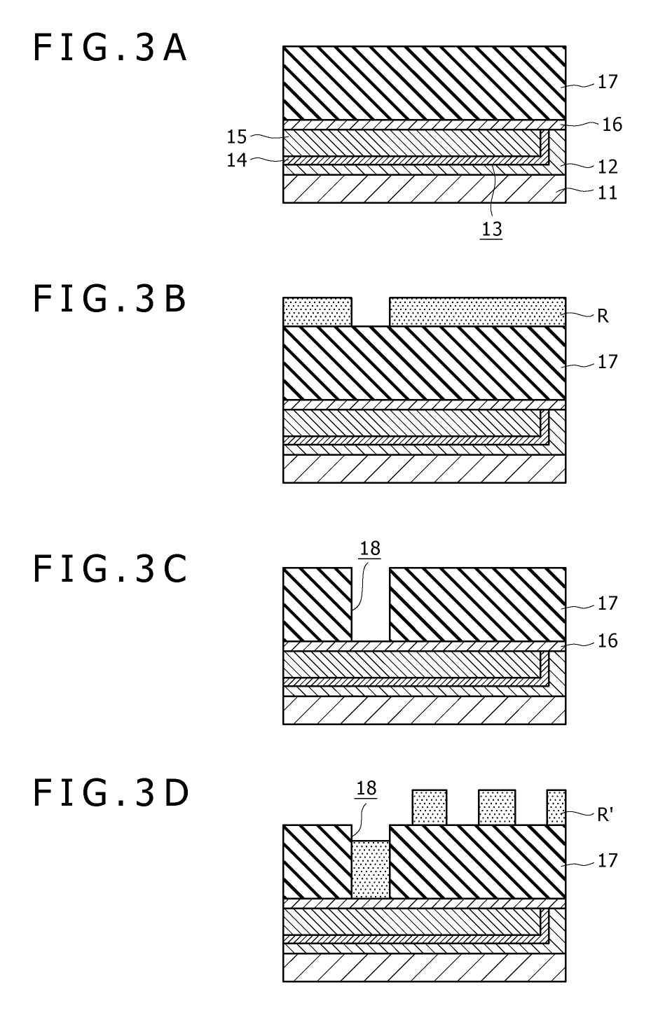

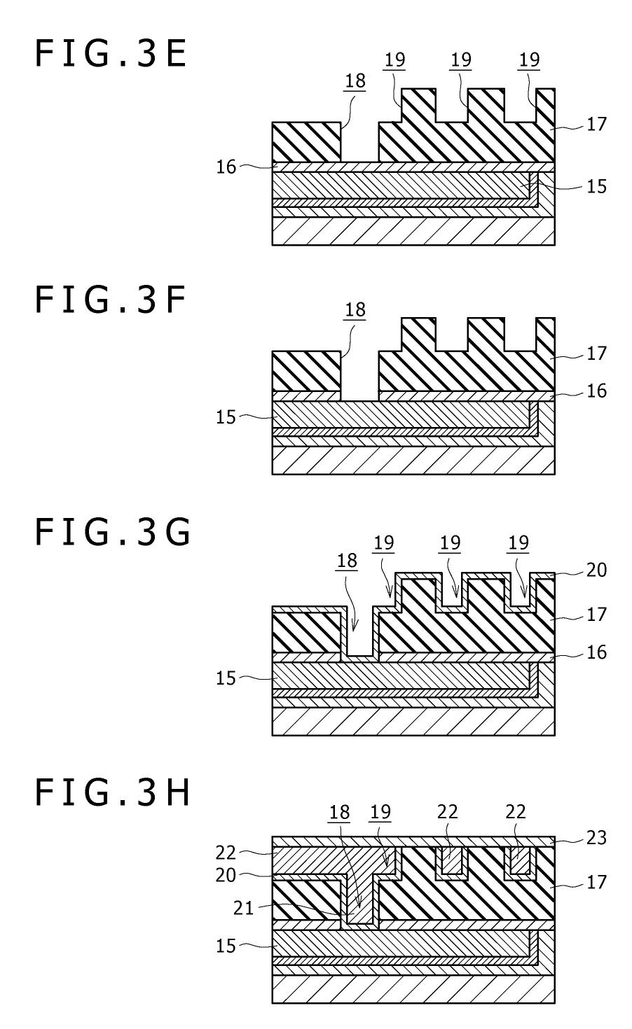

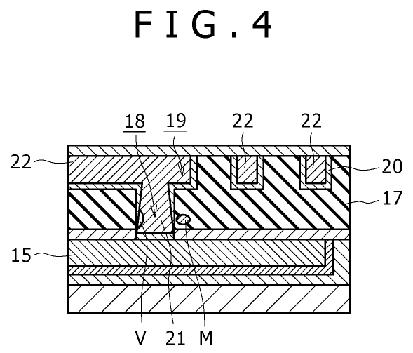

As a method for manufacturing a semiconductor device according to a second embodiment of the present invention, an example in which an interlayer insulating film has a hybrid structure arising from sequential lamination of an inorganic insulating film and an organic insulating film will be described below with reference to FIGS. 2A to 2I as sectional views of manufacturing steps. The same components in the second embodiment as those in the first embodiment are given the same symbols, and detailed description thereof will be omitted. The second embodiment also employs the same manufacturing procedure as that of the first embodiment until the completion of the step of forming an etching stopper film 16 on a lower interconnect 15 and an interlayer insulating film 12, described with FIG. 1A.

Referring initially to FIG. 2A, to form an interlayer insulating film 17′ on the etching stopper film 16, a first insulating layer 17a′ composed of e.g. porous MSQ is formed as an inorganic insulating film to a film thickness of 100 nm, and then a second insulating layer 17b′ composed of e.g. PAE is formed as an organic insulating film on the first insulating layer 17a′ to a film thickness of 80 nm. Thus, the interlayer insulating film 17′ having a hybrid structure arising from sequential lamination of the inorganic insulating film and the organic insulating film is formed.

Subsequently, a first-mask forming layer 41 that is composed of e.g. SiO₂ and has a film thickness of 100 nm is formed on the second insulating layer 17b′ by e.g. PE-CVD. Subsequently, a second-mask forming layer 42 that is composed of SiN and has a film thickness of 50 nm is formed on the first-mask forming layer 41 by e.g. PE-CVD, and then a third-mask forming layer 43 that is composed of SiO₂ and has a film thickness of 50 nm is formed on the second-mask forming layer 42. As described later, the first-mask forming layer 41 will be left as an interconnect insulating film on the second insulating layer 17b′ even after the completion of the device. Therefore, the first-mask forming layer 41 may be formed of an SiO₂ porous film for a lower dielectric constant, although this example employs an SiO₂ non-porous film for the layer 41.

Referring next to FIG. 2B, e.g. a chemically amplified ArF resist is applied on the third-mask forming layer 43, and then an interconnect trench pattern is formed in this resist by general lithography to thereby form a resist pattern R′.

Referring next to FIG. 2C, the third-mask forming layer 43 (see FIG. 2B) is etched by dry etching in which the resist pattern R′ (see FIG. 2B) is used as the mask, to thereby form a third mask 43′ having the interconnect trench pattern. Subsequently, e.g. ashing with an O₂ gas and treatment with an organic amine chemical are carried out, to thereby completely remove the resist pattern R′ and residual fouling generated in the etching treatment.

Subsequently, an anti-reflection film (BARC) 44 composed of e.g. an organic material is formed on the third mask 43′ and the second-mask forming layer 42 so that the steps due to the third mask 43′ are covered. Thereafter, a resist pattern R having a contact hole pattern is formed on the anti-reflection film 44. The resist pattern R is so formed that at least a part of the contact hole pattern of the resist pattern R overlaps with an aperture of the interconnect trench pattern of the third mask 43′.

Referring next to FIG. 2D, the anti-reflection film 44 (see FIG. 2C), the third mask 43′, the second-mask forming layer 42 (see FIG. 2C), and the first-mask forming layer 41 (see FIG. 2C) are etched by dry etching in which the resist pattern R (see FIG. 2C) is used as the mask. Furthermore, the second insulating layer 17b′ is also etched, so that a contact hole 18 that reaches the first insulating layer 17a′ is formed.

The resist pattern R is removed in the etching of the second insulating layer 17b′ simultaneously. The third mask 43′, which remains through this etching, serves as a mask having the interconnect trench pattern. Furthermore, a second mask 42′, which has been pattern-formed through the etching of the second-mask forming layer 42, serves as a mask having the contact hole pattern. After the formation of the contact hole 18, the remaining resist pattern R and the anti-reflection film 44 are removed by etching with an N₂/O₂ gas.

Subsequently, as shown in FIG. 2E, the second mask (SiCN) 42′ is etched by dry etching in which the third mask (SiO₂) 43′ is used as the etching mask. This turns the second mask 42′ into a mask having the interconnect trench pattern. The first-mask forming layer 41 (see FIG. 2A) has been turned into a first mask 41′ having the contact hole pattern. In this dry etching, the first insulating layer 17a′ exposed at the bottom of the contact hole 18 is etched to an intermediate thickness thereof, so that the contact hole 18 is extended downward.

Referring next to FIG. 2F, the lower part of the first insulating layer 17a′ is etched with use of the first mask (SiO₂) 41′ as the etching mask to thereby further extend the contact hole 18 downward so that the etching stopper film 16 is exposed. In this etching, the first mask (SiO₂) 41′ is etched in such a way that the third mask (SiO₂) 43′ (see FIG. 2E) and the second mask (SiCN) 42′ serve as the etching mask, so that an interconnect trench 19 is formed in the first mask 41′.

Referring next to FIG. 2G, the second insulating layer 17b′ that remains at the bottom of the interconnect trench 19 is etched with use of the second mask (SiCN) 42′ (see FIG. 2F) as the etching mask. Thus, the interconnect trench 19 formed in the first mask 41′ is further extended downward, which results in formation of the interconnect trench 19 in the first mask 41′ and the second insulating layer 17b′.

Subsequently, the etching stopper film 16 that remains at the bottom of the contact hole 18 is etched, which allows the contact hole 18 opened below the bottom of the interconnect trench 19 to communicate with the lower interconnect 15.

Referring next to FIG. 2H, plasma treatment with DMPS is carried out for the interlayer insulating film 17′ with the same treatment conditions as those in the first embodiment. This plasma treatment desorbs OH groups that have adhered to the sidewall of the interconnect trench 19 or the contact hole 18, which has been damaged due to the above-described dry etching. Furthermore, the plasma treatment forms on the surface side of the interlayer insulating film 17′ and the first mask 41′ a dense layer (not shown) arising from densification of these layers. Furthermore, because the gas contains C, dangling bonds exposed at the sidewall of the interconnect trench 19 or the contact hole 18 are terminated by carbon-containing groups, and a seal layer 32 that is formed of a carbon-containing film (SiₓC_{y} film) and has a film thickness smaller than 0.5 nm is formed on the interlayer insulating film 17′ and the first mask 41′ in such a manner as to cover the inner walls of the interconnect trench 19 and the contact hole 18, over which the dense layer has been provided. This suppresses moisture absorption of the interlayer insulating film 17′ exposed at the sidewall of the interconnect trench 19 or the contact hole 18, which prevents degassing of water that remains in the interlayer insulating film 17′. Furthermore, the seal layer 32 formed to cover the lower interconnect 15 at the bottom of the contact hole 18 is diffused into the surface side of the lower interconnect 15 due to heat in this plasma treatment, so that a silicide layer S is formed. This enhances the SM resistance and the EM resistance.

In this example, the first mask 41′ is formed of an SiO₂ non-porous film. However, if the first mask 41′ is formed of an SiO₂ porous film, the first mask 41′ exposed at the sidewall of the interconnect trench 19 is also damaged due to dry etching and thus becomes susceptible to moisture absorption. However, provision of the dense layer and the seal layer 32 prevents the moisture absorption of the first mask 41′, which avoids degassing from the first mask 41′.

Steps subsequent to the plasma treatment are carried out similarly to a general dual damascene method. Specifically, referring to FIG. 2I, a barrier film 20 composed of e.g. Ta is deposited by e.g. sputtering on the interlayer insulating film 17′ and the first mask 41′ in such a manner as to cover the inner walls of the interconnect trench 19 and the contact hole 18. Subsequently, by electroplating or sputtering, a conductive film (not shown) composed of e.g. Cu is so formed on the barrier film 20 that the interconnect trench 19 and the contact hole 18 are filled.

Thereafter, the part unnecessary for the interconnect pattern of the conductive film (not shown), the barrier film 20 and the seal layer 32, and a part of the first mask 41′ are removed by CMP, so that a via 21 is formed in the contact hole 18 and an upper interconnect 22 is formed in the interconnect trench 19. This results in the state in which a silicide layer S is provided in a part of the lower interconnect 15 near the interface with the via 21. Thereafter, an etching stopper film 23 composed of e.g. SiCN is formed on the upper interconnect 22 and the first mask 41′.

As subsequent steps, the steps described with FIGS. 2A to 2I are repeated, which can form a multilevel interconnect structure having a dual damascene structure.

According to the above-described method for manufacturing a semiconductor device and a semiconductor device obtained by this method, plasma treatment is carried out by using a DMPS gas for the interlayer insulating film 17′ and the first mask 41′ in which the interconnect trench 19 and the contact hole 18 have been formed through dry etching. Thus, OH groups that have adhered to the sidewalls of the interconnect trench 19 and the contact hole 18 are desorbed, and the surface side of the interlayer insulating film 17′ and the first mask 41′ are densified, so that a dense layer is formed. Furthermore, dangling bonds exposed at the sidewalls of the interconnect trench 19 and the contact hole 18 are terminated by carbon-containing groups, and the seal layer 32 formed of an SiₓC_{y} film is formed on the surface of the dense layer. Therefore, the second embodiment can offer the same advantages as those by the first embodiment.

In the above-described example, as described with FIG. 2H, the above-described plasma treatment is carried out after the steps of removing the etching stopper film 16 at the bottom of the contact hole 18 and forming the interconnect trench 19 in the second insulating layer 17b′ and before the step of forming the barrier film 20. However, in an embodiment of the present invention, the plasma treatment may be carried out at any timing as long as the timing is subsequent to the step of forming the contact hole 18 or the interconnect trench 19 and previous to the step of forming the barrier film 20.

For example, the plasma treatment may be carried out after the step described with FIG. 2D, in which the contact hole 18 that reaches the first insulating layer 17a′ is formed, and before the step described with FIG. 2E, in which the contact hole 18 is extended downward to an intermediate thickness of the first insulating layer 17a′. Alternatively, the plasma treatment may be carried out after the step described with FIG. 2E, in which the contact hole 18 is extended downward to an intermediate thickness of the first insulating layer 17a′, and before the step described with FIG. 2F, in which the contact hole 18 is extended downward to reach the etching stopper film 16. Alternatively, the plasma treatment may be carried out after the step described with FIG. 2F, in which the contact hole 18 is extended downward to reach the etching stopper film 16 and the interconnect trench 19 is formed in the first mask 41′, and before the step described with FIG. 2G, in which the etching stopper film 16 at the bottom of the contact hole 18 is removed and the interconnect trench 19 is formed in the second insulating layer 17b′. More alternatively, plural times of the plasma treatment may be carried out in such a way that the treatment is carried out at any two or more of the above-described timings.

In the above-described examples according to the first and second embodiments, the interconnect trench 19 is formed after the contact hole 18 has been formed in the interlayer insulating film 17. However, an embodiment of the present invention is applicable to the case of forming the interconnect trench 19 before formation of the contact hole 18. Moreover, the above-described examples relate to a method for manufacturing a semiconductor device through a dual damascene method. However, the present invention is not limited thereto but an embodiment thereof can be applied also to a single damascene method.

It should be understood by those skilled in the art that various modifications, combinations, sub-combinations and alterations may occur depending on design requirements and other factors insofar as they are within the scope of the appended claims or the equivalents thereof.

What is claimed is:

1. A method for manufacturing a semiconductor device, the method comprising:
the first step of forming an insulating film over a substrate of which surface side has a first conductive layer, and forming a recess in the insulating film by dry etching;
the second step of carrying out plasma treatment for the insulating film with use of a gas that contains carbon or silicon; and
the third step of forming a second conductive layer buried in the recess for which the plasma treatment has been carried out.

2. The method for manufacturing a semiconductor device according to claim 1, wherein
the gas contains both carbon and silicon.

3. The method for manufacturing a semiconductor device according to claim 1, wherein
the insulating film includes a low dielectric constant film having a dielectric constant lower than that of a silicon oxide, and the low dielectric constant film is exposed at a sidewall of the recess.

4. The method for manufacturing a semiconductor device according to claim 1, wherein
the insulating film includes a laminated film formed of an organic insulating film and an inorganic insulating film.

5. The method for manufacturing a semiconductor device according to claim 1, wherein
in the first step, the recess that reaches the first conductive layer is formed.

6. The method for manufacturing a semiconductor device according to claim 1, wherein
after the second step and before the third step, the recess is extended downward to reach the first conductive layer.

7. The method for manufacturing a semiconductor device according to claim 1, wherein
after the second step and before the third step, a barrier film for preventing diffusion of a conductive material from the second conductive layer into the insulating film is formed to cover an inner wall of the recess.

8. A semiconductor device comprising:
a substrate configured to have a first conductive layer on a surface side of the substrate;
an insulating film configured to be provided over the substrate; and
a second conductive layer configured to be buried in a recess that is provided in the insulating film and reaches the first conductive layer, wherein
a dense layer arising from densification of the insulating film is provided in a part of the insulating film near an interface between the insulating film and the second conductive layer, and a seal layer containing carbon is provided between the dense layer and the second conductive layer.

9. The semiconductor device according to claim 8, wherein
a silicide layer is provided in a part of the first conductive layer near an interface between the first conductive layer and the second conductive layer.

10. A semiconductor device comprising:
a substrate configured to have a first conductive layer on a surface side of the substrate;
an insulating film configured to be provided over the substrate; and
a second conductive layer configured to be buried in a recess that is provided in the insulating film and reaches the first conductive layer, wherein
a dense layer arising from densification of the insulating film is provided in a part of the insulating film near an interface between the insulating film and the second conductive layer, and a silicide layer is provided in a part of the first conductive layer near an interface between the first conductive layer and the second conductive layer.
